(19) United States
(12) Patent Application Publication
(10) Pub. No.: US 2015/0235381 A1
(43) Pub. Date: Aug. 20, 2015

(54) APPARATUS FOR IMAGING PLASMA PARTICLES AND METHOD FOR DETECTING ETCHING END POINT USING SAME

(71) Applicant: INDUSTRY-ACADEMIA COOPERATION GROUP OF SEJONG UNIVERSITY, Gwangjin-gu Seoul (KR)

(72) Inventor: Byung Whan Kim, Seoul (KR)

(73) Assignee: INDUSTRY-ACADEMIA COOPERATION GROUP OF SEJONG UNIVERSITY, Gwangjin-gu, Seoul (KR)

(21) Appl. No.: 14/426,991

(22) PCT Filed: Sep. 3, 2013
(86) PCT No.: PCT/KR2013/007919

§ 371 Date: Mar. 10, 2015

(30) Foreign Application Priority Data
Sep. 10, 2012 (KR) 10-2012-0099999

(51) Int. Cl. G06T 7/40; H04N 5/372; H01J 37/32

(52) U.S. Cl. CPC G06T 7/408; H01J 37/32963; H04N 5/372; H01J 2237/334; H01J 2237/2445; H01J 2237/24592

(57) ABSTRACT

Provided are an apparatus for photographing plasma particles and a method for detecting an etch endpoint using the apparatus. The method includes: receiving, according to time, a captured image of particles in a plasma chamber in which a thin film on a wafer is being etched; calculating a number of pixels within a predetermined grayscale range in the captured image; calculating, according to points of time, an accumulated average value of the number of pixels up to a current point of time; and detecting an etch endpoint that is a completion time of etching by using the accumulated average value calculated according to points of time.

### TECHNICAL FIELD

The present invention relates to an apparatus for photographing plasma particles and a method for detecting an etch endpoint using the apparatus, and more particularly, to an apparatus for photographing plasma particles, which is capable of detecting a time when etching is completed during a thin film etching process using plasma, and a method for detecting an etch endpoint using the apparatus.

### BACKGROUND ART

Generally, an etch endpoint denotes a moment when a thin film deposited in a uniform thickness is completely removed while etching the thin film by using plasma. If the etch endpoint is not detected at a right moment, another thin film adjacent to the thin film or a wafer below the thin film may be etched and damaged. Normally, the thin film is completely removed via an overetching process when the etch endpoint is reached, and thus an additional process of the overetching process is required.

Generally, an optical emission spectroscopy (OES) is used as a sensor to detect an etch endpoint during a device manufacturing process. A technology for determining an etch endpoint by using an OES is disclosed in KR 10-2003-0000274.

The OES is used in a method for measuring intensity of a light reflected from an object, wherein intensity of a wavelength corresponding to a certain species related to a material being etched is measured and monitored. Detected intensity remarkably decreases at a time when etching is ended, and an etch endpoint is determined by tracking such intensity variation.

The OES mainly uses a method of monitoring a certain wavelength of a reflected light provided by a center portion of a plasma device. However, since a pattern interval of an etch target portion is generally dozens of nm and an etching point is very minute, intensity of the certain wavelength is very weak, and thus it is difficult to accurately detect an etch endpoint. Also, in a light consisting of particles having several wavelengths, accuracy of an etch endpoint may be decreased since the particles may interfere with a light of a certain wavelength to be monitored.

### DETAILED DESCRIPTION OF THE INVENTION

### Technical Problem

The present invention provides an apparatus for photographing plasma particles, which is capable of easily detecting an etch endpoint by using a captured image of particles in a plasma chamber for etching a thin film, and a method for detecting an etch endpoint using the apparatus.

### Technical Solution

According to an aspect of the present invention, there is provided a method for detecting an etch endpoint using an apparatus for photographing plasma particles, the method including: receiving, according to time, a captured image of particles in a plasma chamber in which a thin film on a wafer is being etched; calculating a number of pixels within a predetermined grayscale range in the captured image; calculating, according to points of time, an accumulated average value of the number of pixels up to a current point of time; and detecting an etch endpoint that is a completion time of etching by using the accumulated average value calculated according to points of time.

The accumulated average value at an m-th point of time may be calculated according to an equation below: Accumulated

$${Average}_{m} = \frac{{\sum }_{i = 1}^{m} {N}_{i}}{m} ,$$

wherein Nᵢ denotes the number of pixels calculated from a captured image at the m-th point of time, and m denotes an integer equal to or higher than 2.

The detecting of the etch endpoint may include determining a point of time when the accumulated average value is minimum as the etch endpoint.

The detecting of the etch endpoint may include: calculating a difference value between an accumulated average value at the m-th point of time and an accumulated average value at an m−1-th point of time; calculating, according to points of time, an error accumulated average value that is an accumulated average value of the difference value; and determining a point of time when the error accumulated average value is outside a reference range as the etch endpoint.

The captured image may be an image restored in a predetermined space in the plasma chamber.

The captured image may be an image restored in a space corresponding to a plasma sheath.

The apparatus may include: a laser unit for generating a laser beam; a beam splitter for splitting the generated laser beam into a beam in a horizontal direction facing the plasma chamber and a beam in a vertical direction facing upward; a beam expander for expanding the beam in the horizontal direction towards a chuck upper portion where a wafer is placed in the plasma chamber; and a charge coupled device (CCD) sensor for obtaining the captured sensor by receiving a beam reflected from an inner wall of the plasma chamber after passing through the chuck upper portion, through the beam splitter.

According to another aspect of the present invention, there is provided an apparatus for capturing plasma particles, the apparatus including: an image input unit for receiving, according to time, a captured image of particles in a plasma chamber in which a thin film on a wafer is being etched; a first calculator for calculating a number of pixels within a predetermined grayscale range in the captured image; a second calculator for calculating, according to points of time, an accumulated average value of the number of pixels up to a current point of time; and an endpoint detector for detecting an etch endpoint that is a completion time of etching by using the accumulated average value calculated according to points of time.

### Advantageous Effects

According to an apparatus for photographing plasma particles and a method for detecting an etch endpoint using the apparatus, an etch endpoint may be easily detected by obtaining, according to time, a captured image of particles forming a material being etched in a plasma chamber for etching a thin film, and calculating an accumulated average value of a number of pixels in a predetermined grayscale range from the captured image.

### DESCRIPTION OF THE DRAWINGS

FIG. 1 is schematic diagrams of optical microscopes according to embodiments of the present invention;

FIG. 2 is a block diagram of an apparatus for photographing plasma particles, according to an embodiment of the present invention;

FIG. 3 is a flowchart illustrating a method for detecting an etch endpoint using the apparatus of FIG. 2, according to an embodiment of the present invention;

FIG. 4 illustrates an example of a captured image at a predetermined point of time received in operation S310 of the method of FIG. 3;

FIG. 5 is a graph obtained by analyzing a particle count according to grayscales with respect to a region where y=1 to 1700 from the captured image of FIG. 4;

FIG. 6 is graphs obtained by calculating, according to time, numbers of pixels in a predetermined grayscale range in the captured image of FIG. 4 for operation S320 of the method of FIG. 3;

FIG. 7 is graphs of accumulated average values according to points of time obtained from the graphs of FIG. 6 during operation S330 of the method of FIG. 3; and

FIG. 8 is a graph showing error accumulated averages obtained through the graphs of FIG. 7.

### MODE OF THE INVENTION

Hereinafter, the present invention will be described more fully with reference to the accompanying drawings, in which exemplary embodiments of the invention are shown.

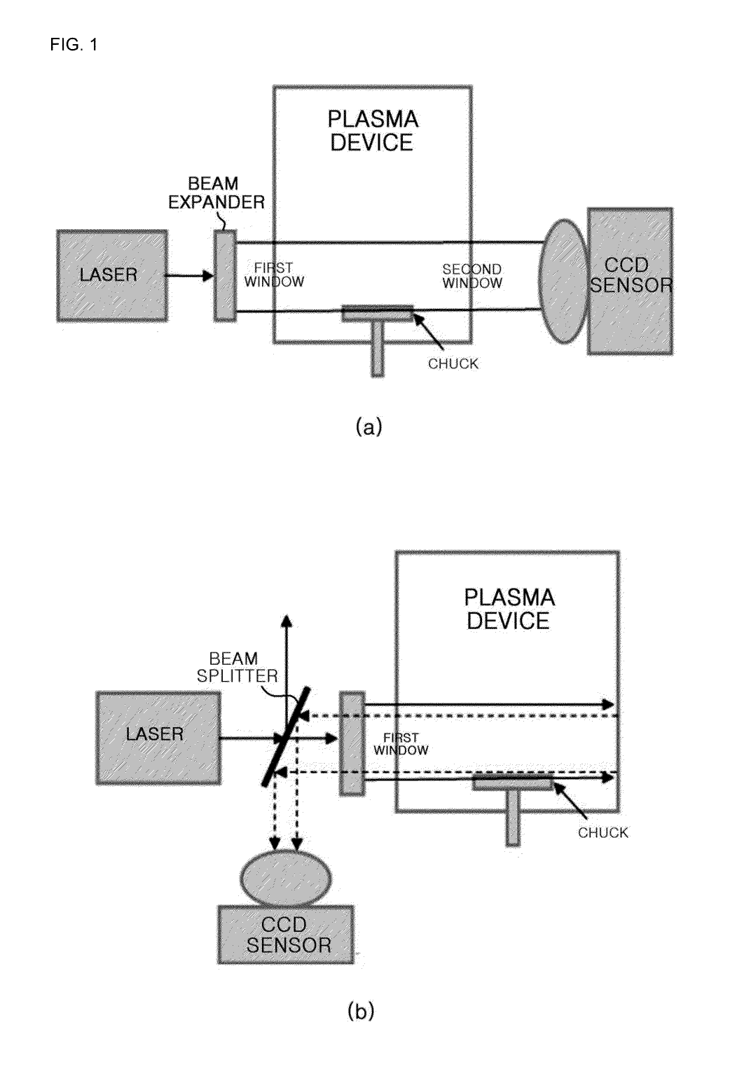

FIG. 1 is schematic diagrams of optical microscopes according to embodiments of the present invention. The two optical microscopes in FIG. 1 photograph particles in a plasma sheath space above a wafer, including the wafer.

FIG. 1 (a) shows a general in-line optical system including a laser, a beam expander, and a charge coupled device (CCD) sensor. Two windows (a first window and a second window) are required in a plasma device, i.e., a plasma chamber. A wafer is placed on a chyck, and a thin film that is an etching target is disposed on the wafer. A separate mask may be disposed on the thin film such that only an etching point is exposed.

A beam irradiated from the laser is expanded in the beam expander to light up an upper portion of the chuck including the chuck. Here, information about material particles absorbing, reflecting, or transmitting the beam is stored in the CCD sensor. Generally, a sheath space is a space where a number of electrons is smaller than a number of ions and is generated near the chuck.

FIG. 1 (b) shows a modified example of a general on-axis optical system, wherein a reflection plate is not disposed on an upper portion of a beam splitter. FIG. 1 (b) shows an optical structure of an apparatus for photographing plasma particles, which includes a laser unit, a beam splitter, a beam expander, and a CCD sensor. One window (a first window) is required in a plasma chamber.

The laser unit generates a laser beam. The beam splitter splits the generated laser beam to a beam in a horizontal direction facing the plasma chamber and a beam in a vertical direction facing upward. The beam expander expands the beam in the horizontal direction towards a chuck upper portion where a wafer is placed in the plasma chamber. The CCD sensor obtains a captured image on particles in the plasma chamber by receiving a beam reflected from an inner wall of the plasma chamber after passing through the chuck upper portion, through the beam splitter.

In a general on-axis optical system, a reflection plate is disposed on an upper portion of a beam splitter, and thus a beam in a vertical direction is incident on a CCD sensor below the reflection plate as the beam in the vertical direction is reflected at the reflection plate. However, in the current embodiment, since a reflection plate is not present, the beam in the vertical direction from among the beams in the horizontal and vertical directions obtained in the beam splitter is not used.

In FIG. 1 (b), the beam irradiated from the laser is split into the beams in the horizontal and vertical directions by the beam splitter, and the beam in the horizontal direction passes through the first window to light up the upper portion of the chuck, and then is reflected again at an opposite wall of the plasma chamber. The beam reflected at the opposite wall reacts with an etching material and plasma particles, and distribution of the reacted plasma particles is stored in the CCD sensor.

In both FIG. 1 (a) and (b), resolution of the plasma particles may be increased by providing various filters, such as a spatial filter, in front of the CCD sensor.

By using an image captured through the optical microscopes of FIG. 1, a particle count distribution in a predetermined space in a horizontal (or vertical) direction of the plasma chamber may be obtained. An algorithm used for space decomposition of the particle count distribution is Fresnel zone transformation.

A CCD image obtained by using the optical microscopes of FIG. 1 originally consists of X- and Y-axes that is a 2-dimensional (2D) plane, but an object may be classified in a 3D space by moving the 2D plane in a Z-axis by restoring the CCD image. Such a restoration technology is well known in the related art, and is applied in calculating electron or ion distribution in a plasma space. A restoration equation is represented by Equation 1 below.

h(r, c)=F⁻¹[F[u(x, y)]exp(i(kₓ²+k_{y}²)d)] [Equation 1]

Here, u(x,y) denotes an input image and d denotes a distance away from an object. For example, d may denote a distance between the CCD sensor and a predetermined point in the plasma chamber. kₓ and k_{y} each denote a singularity function for obtaining a Fresnel zone pattern. h(r,c) is divided into a real number portion and an imaginary number portion. Equation 2 is used to calculate a phase and Equation 3 is used to calculate a size, and thus the object may be imagified.

$$\begin{matrix}Φ ( r , c ) = arctan \frac{Im [ h ( r , c ) ]}{Re [ h ( r , c ) ]} & [ Equation 2 ] \\ I ( r , c ) = \vert h ( r , c ) \vert & [ Equation 3 ]\end{matrix}$$

By adjusting the distance d in Equation 1, a 2D particle distribution in a predetermined space in the plasma chamber may be restored through Equation 3. Equation 3 is obtained by using image information of the real number portion and the imaginary number portion. The image information of the real number portion is similar to an image restored through Equation 3, and thus may replace a restored image.

Here, it is possible to obtain a 3D particle distribution by obtaining and combining 2D particle distributions with respect to an entire distance in the horizontal (or vertical) direction of the plasma chamber. A 3D endpoint may be detected by detecting a particle count variation near a wafer (for example, a plasma sheath region near a wafer) from 2D images restored in the entire horizontal or vertical direction of the plasma chamber, and combining the 2D images.

Hereinafter, an apparatus for photographing plasma particles using an image captured through the optical microscope, and a method for detecting an etch endpoint using the apparatus will now be described in detail. For example, the apparatus includes the optical structure of FIG. 1 (b).

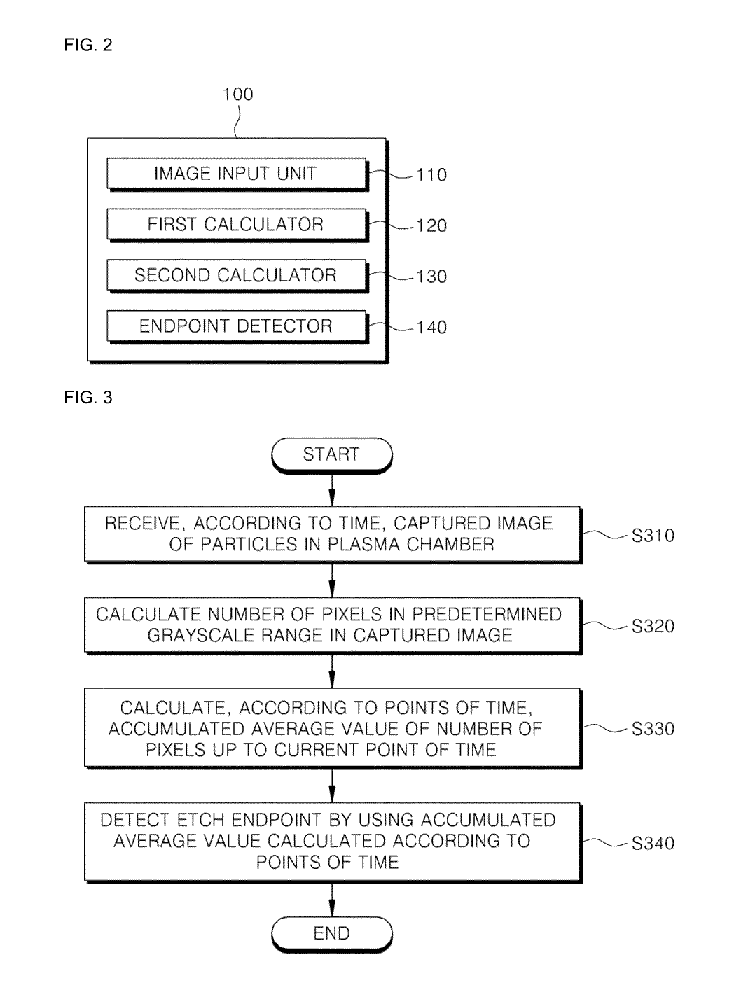

FIG. 2 is a block diagram of an apparatus 100 for photographing plasma particles, according to an embodiment of the present invention. The apparatus 100 includes an image input unit 110, a first calculator 120, a second calculator 130, and an endpoint detector 140.

The image input unit 110 receives, according to time, a captured image of particles in a plasma chamber in which a thin film on a wafer is being etched. Accordingly, a captured image is obtained according to points of time.

The first calculator 120 calculates a number of pixels in a predetermined grayscale range in the captured image. The first calculator 120 calculates the number of pixels in the predetermined grayscale range with respect to the captured image according to the points of time.

The second calculator 130 calculates, according to points of time, an accumulated average value of the number of pixels up to a current point of time. An accumulated average denotes an average of the numbers accumulated from an initial point of time to the current point of time.

The endpoint detector 140 detects an etch endpoint that is a completion time of etching by using the accumulated average value calculated according to points of time. By detecting the etch endpoint, a surface of an adjacent thin film or a wafer below the thin film may be prevented from being damaged.

Here, the captured image used to detect the etch endpoint may correspond to an image restored in a predetermined space of the plasma chamber, and in detail, may correspond to an image restored in a space corresponding to a plasma sheath.

FIG. 3 is a flowchart illustrating a method for detecting an etch endpoint using the apparatus 100 of FIG. 2, according to an embodiment of the present invention. The method according to the current embodiment will now be described in detail with reference to FIGS. 2 and 3.

First, the image input unit 110 receives, according to time, a captured image of particles in a plasma chamber in which a thin film on a wafer is being etched, in operation S310. In other words, the image input unit 110 receives a plurality of captured images obtained according to points of time. Operation S310 is performed while the thin film is etched in the plasma chamber.

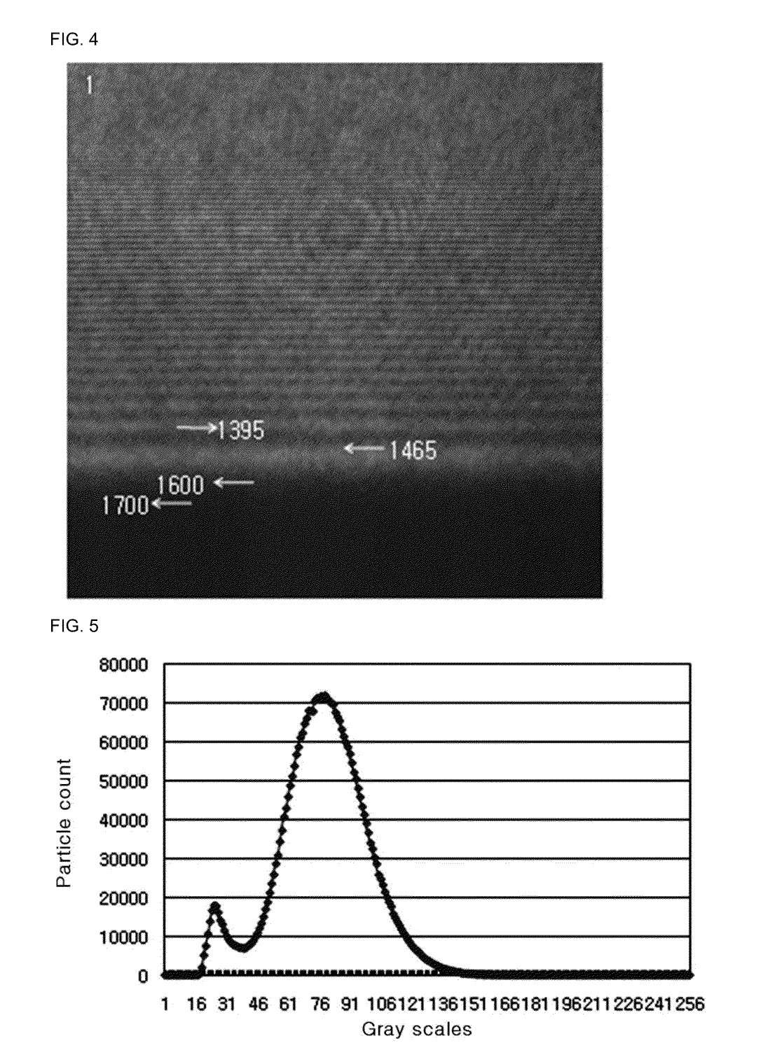

FIG. 4 illustrates an example of a captured image at a predetermined point of time received in operation S310 of the method of FIG. 3. In the captured image of FIG. 4, an uppermost pixel layer portion corresponds to a point where y=1 and a lowermost pixel layer portion corresponds to a point where y=2048. A lower portion of the captured image where y is from about 1500 to about 1739 is a portion including a plasma sheath region, and is near a chuck.

FIG. 5 is a graph obtained by analyzing a particle count according to grayscales with respect to a region where y=1 to 1700 from the captured image of FIG. 4. Here, the particle count denotes a number of pixels.

In FIG. 5, a horizontal axis denotes a grayscale value and a vertical axis denotes a number of pixels according to grayscales. Here, the number of pixels corresponds to the particle count. In the current embodiment, the grayscale value of a pixel is used in 8 bits, and thus the grayscale value has a value from 0 to 255 or from 1 to 256.

In FIG. 5, the numbers of pixels are calculated according to the grayscale values (1 to 256) with respect to the region where y=1 to 1700 in the plasma space of the captured image of FIG. 4, and the numbers of pixels are shown in a distribution function. In this regard, a total number of pixels corresponding to a grayscale value where g=79 from pixels forming an image where y=1 to 1700 is about 70,000. In other words, a grayscale value where a maximum particle count is generated is 79.

Then, the first calculator 120 calculates, according to points of time, a number of pixels in a predetermined grayscale range in the obtained captured image, in operation S320.

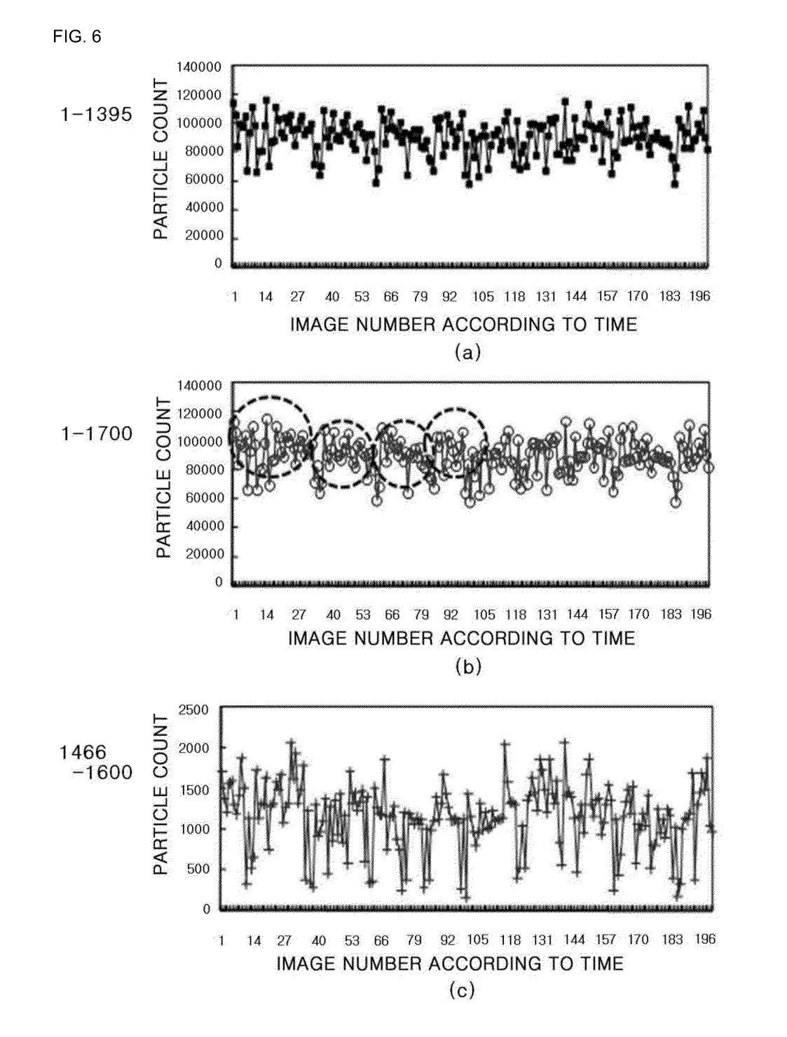

FIG. 6 is graphs obtained by calculating, according to time, numbers of pixels in a predetermined grayscale range in the captured image of FIG. 4 for operation S320 of the method of FIG. 3. Each graph is obtained by capturing 200 images for 10 seconds (capturing speed: 20 images/sec). In the graphs, a horizontal axis denotes an index (in a range from 1 to 200) with respect to each point of time, and a vertical axis denotes a number of pixels (particle count) in a predetermined grayscale range calculated at each point of time.

Here, FIG. 6 (a) shows a number of pixels in a predetermined grayscale range (g=111 to 120) calculated according to photographing points of time with respect to a region where y=1 to 1395. FIG. 6 (b) and (c) show numbers of pixels in the same manner as in FIG. 6 (a) respectively with respect to ranges where y=1 to 1700 and y=1466 to 1600. The graph in FIG. 6 (c) corresponds to a region of a sheath space.

Referring to FIG. 6 (b), particle count patterns in broken line circles are similarly repeated, denoting that an etching process is being performed. During an etching process, numbers of pixels in a predetermined grayscale range are repeated in a certain pattern according to time. Such a repeated certain pattern is used as an important clue in detecting a plasma state during the etching process.

After operation S320, an accumulated average value of the number of pixels up to a current point of time is calculated according to points of time, in operation S330. Operation S330 is performed by the second calculator 130.

An accumulated average value at an m-th point of time may be calculated according to Equation 4 below.

$$Accumulated {Average}_{m} = \frac{{\sum }_{i = 1}^{m} {N}_{i}}{m} \qquad [ Equation 4 ]$$

Here, Nᵢ denotes a number of pixels calculated in an image at an m-th point of time, and m denotes a number of images used to calculate an accumulated average value and is an integer equal to or higher than 2.

For example, accumulated average₃ is calculated by obtaining a sum of numbers of pixels in images at first through third points of time, and dividing the sum by 3. Since Equation 4 corresponds to the accumulated average value, a smallest value for m is 2.

Here, the accumulated average value at the m-th point of time may be replaced by Equation 5 below.

$$Accumulated {Average}_{m} = \frac{( m - 1 ) \times accumulated {average}_{m - 1} + {N}_{m}}{m} \qquad [ Equation 5 ]$$

Here, Nₘ denotes a number of pixels calculated in an image at an m-th point of time during operation S320. An accumulated averageₘ₋₁denotes an accumulated average value obtained according to Equation 4 at a previous point of time, i.e., at an m−1-th point of time.

By using Equation 5, a calculation time may be reduced compared to when Equation 4 is used. In other words, according to Equation 5, a calculation speed may be increased since only the accumulated average value at the previous point of time (accumulated averageₘ₋₁) and the number of pixels calculated at the current point of time (Nₘ) are required.

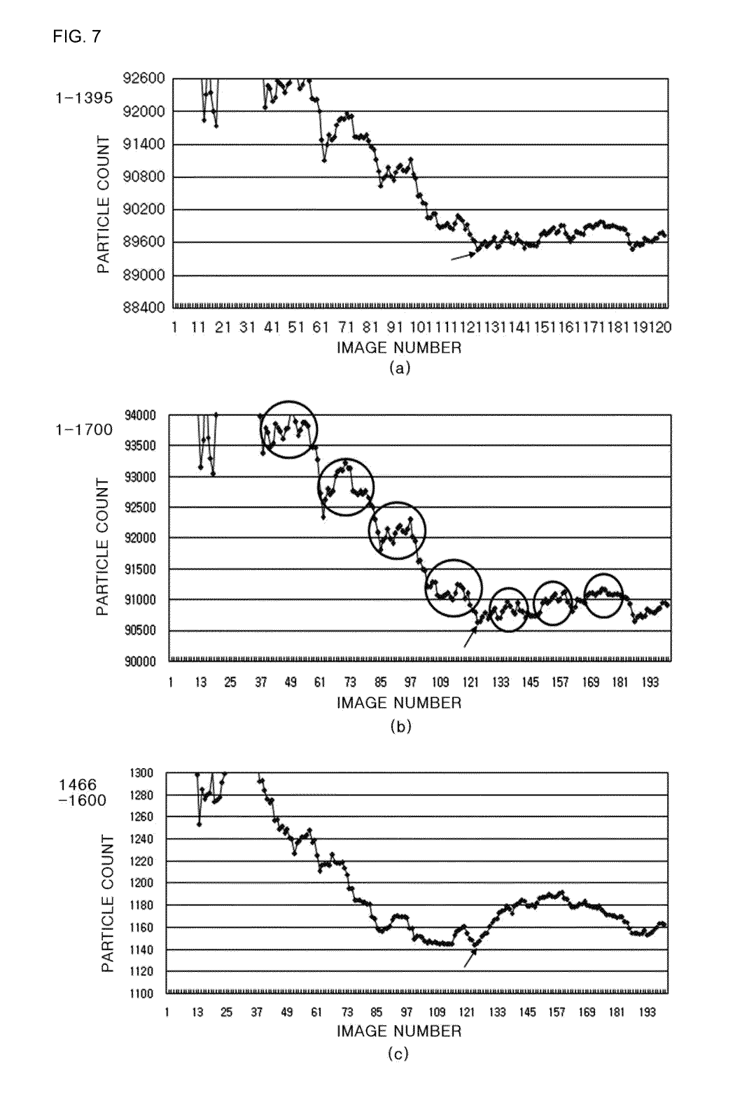

FIG. 7 is graphs of accumulated average values according to points of time obtained from the graphs of FIG. 6 during operation S330 of the method of FIG. 3. FIG. 7 shows accumulated average values according to time, obtained according to Equation 4 or 5.

In this regard, the endpoint detector 140 detects an etch endpoint that is a completion time of etching by using the accumulated average value calculated according to points of time, in operation S340.

The accumulated average values of FIG. 7 obtained from the graphs of FIG. 6 gradually decrease according to time and become flat at a predetermined time. Referring to circles in FIG. 7 (b), circles before a point of time indicated by an arrow show patterns a thin film is etched, and circles after the point of time indicated by the arrow show a wafer (Si) below the thin film (oxide thin film) being etched. An etching pattern of the wafer is similar to that of the thin film. An accumulated average particle count decreases according to time, and stops decreasing based on the point of time indicated by the arrow.

In the current embodiment, a thickness of the oxide thin film before etching is 12 Å and an etching condition in a plasma chamber is 2 Å/sec, and thus the oxide thin film having the thickness of 12 Å may be completely etched after around 6 seconds.

In the graphs of FIG. 7, an accumulated average value has a minimum value at around 6 seconds. Accordingly, in operation S340, a point of time when the accumulated average value is minimum may be determined to be the etch endpoint.

In FIG. 7, an etch endpoint is detected in a 125th image, i.e., at a point of time corresponding to 6.125 seconds, in all plasma spaces (regions where y=1 to 1395, y=1 to 1700, y=1466 to 1600), and the detected etch endpoint almost matches an estimated etch endpoint.

As such, in the current embodiment an etch endpoint may be detected by only using an accumulated average value of particle counts. Alternatively, in operation S340, the etch endpoint may be determined by using an error accumulated value with respect to the accumulated average value of FIG. 7, as follows.

First, the endpoint detector 140 calculates a difference value between the accumulated average value at the m-th point of time shown in FIG. 7, and the accumulated average value at the m-th point of time. The difference value may be calculated according to Equation 6 below, wherein Eₘ denotes the difference value.

Eₘ=accumulated averageₘ−accumulated averageₘ₋₁; m=3, 4, 5, . . . [Equation 6]

Then, the endpoint detector 140 calculates, according to points of time, an error accumulated average value that is an accumulated average value of the difference values Eₘ. Such an error accumulated average value may be obtained according to a principle of Equation 4, or a calculation process may be simplified according to a principle of Equation 5.

When the principle of Equation 5 is used, the error accumulated average value at an m-th point of time may be calculated according to Equation 7 below.

$$error accumulatd {average}_{m} = \frac{( m - 3 ) \times error accumulated {average}_{m - 1} + {E}_{m}}{m - 2} \qquad [ Equation 7 ]$$

Here, m also denotes an integer equal to or higher than 3 (m=3, 4, 5 . . . ).

In other words, since only an error accumulated average value (error accumulated averageₘ₋₁) calculated at a previous point of time and an error value Eₘ collected at a current point time are required, a calculation process may be simplified and a calculation time may be reduced.

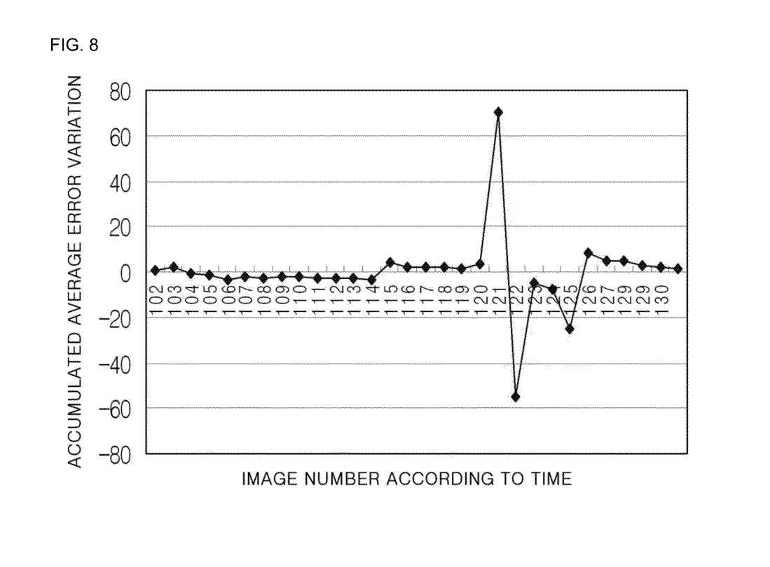

FIG. 8 is a graph showing error accumulated averages obtained through the graphs of FIG. 7. FIG. 8 is a graph obtained by using Equation 7, and shows an average variation of accumulated errors according to time. Here, points of time lower than 101 and higher than 132 are not shown for convenience of description.

Referring to FIG. 8, an error accumulated average rapidly decreases based on a point of time of 121 (6 seconds), and then increases again after a point of time of 125 (6.24 seconds). Before etching is ended, a rapid change shown before 0.25 seconds may be used as a useful variation for detecting an etch endpoint. In other words, in the current embodiment, a point of time when the error accumulated average value exceeds a reference range is determined to be the etch endpoint. Here, the point of time when the error accumulated average value exceeds the reference range or a point of time around thereof may be determined as the etch endpoint.

According to the apparatus and the method of the present invention, an etch endpoint may be easily detected by obtaining, according to time, a captured image of particles forming a material being etched in a plasma chamber for etching a thin film, and calculating an accumulated average value of a number of pixels in a predetermined grayscale range from the captured image.

While the present invention has been particularly shown and described with reference to exemplary embodiments thereof, it will be understood by those of ordinary skill in the art that various changes in form and details may be made therein without departing from the spirit and scope of the present invention as defined by the following claims.

### EXPLANATION OF REFERENCE NUMERALS

| | |
|---|---|
| 100: Apparatus for Photographing | 110: Image Input Unit |
| Plasma Particles | |
| 120: First Calculator | 130: Second Calculator |
| 140: Endpoint Detector | |

1. A method for detecting an etch endpoint using an apparatus for photographing plasma particles, the method comprising:
receiving, according to time, a captured image of particles in a plasma chamber in which a thin film on a wafer is being etched;
calculating a number of pixels within a predetermined grayscale range in the captured image;
calculating, according to points of time, an accumulated average value of the number of pixels up to a current point of time; and
detecting an etch endpoint that is a completion time of etching by using the accumulated average value calculated according to points of time.

2. The method of claim 1, wherein the accumulated average value at an m-th point of time is calculated according to an equation below:
$$Accumulated {Average}_{m} = \frac{{\sum }_{i = 1}^{m} {N}_{i}}{m}$$
wherein Nᵢ denotes the number of pixels calculated from a captured image at the m-th point of time, and m denotes an integer equal to or higher than 2.

3. The method of claim 2, wherein the detecting of the etch endpoint comprises determining a point of time when the accumulated average value is minimum as the etch endpoint.

4. The method of claim 2, wherein the detecting of the etch endpoint comprises:
calculating a difference value between an accumulated average value at the m-th point of time and an accumulated average value at an m−1-th point of time;
calculating, according to points of time, an error accumulated average value that is an accumulated average value of the difference value; and
determining a point of time when the error accumulated average value is outside a reference range as the etch endpoint.

5. The method of claim 1, wherein the captured image is an image restored in a predetermined space in the plasma chamber.

6. The method of claim 1, wherein the captured image is an image restored in a space corresponding to a plasma sheath.

7. The method of claim 1, wherein the apparatus comprises:
a laser unit for generating a laser beam;
a beam splitter for splitting the generated laser beam into a beam in a horizontal direction facing the plasma chamber and a beam in a vertical direction facing upward;
a beam expander for expanding the beam in the horizontal direction towards a chuck upper portion where a wafer is placed in the plasma chamber; and
a charge coupled device (CCD) sensor for obtaining the captured sensor by receiving a beam reflected from an inner wall of the plasma chamber after passing through the chuck upper portion, through the beam splitter.

8. An apparatus for capturing plasma particles, the apparatus comprising:
an image input unit for receiving, according to time, a captured image of particles in a plasma chamber in which a thin film on a wafer is being etched;
a first calculator for calculating a number of pixels within a predetermined grayscale range in the captured image;
a second calculator for calculating, according to points of time, an accumulated average value of the number of pixels up to a current point of time; and
an endpoint detector for detecting an etch endpoint that is a completion time of etching by using the accumulated average value calculated according to points of time.

9. The apparatus of claim 8, wherein the accumulated average value at an m-th point of time is calculated according to an equation below:
$$Accumulated {Average}_{m} = \frac{{\sum }_{i = 1}^{m} {N}_{i}}{m}$$
wherein Nᵢ denotes the number of pixels calculated from a captured image at the m-th point of time, and m denotes an integer equal to or higher than 2.

10. The apparatus of claim 9, wherein the endpoint detector determines a point of time when the accumulated average value is minimum as the etch endpoint.

11. The apparatus of claim 9, wherein the endpoint detector calculates a difference value between an accumulated average value at the m-th point of time and an accumulated average value at an m−1-th point of time, calculates, according to points of time, an error accumulated average value that is an accumulated average value of the difference value, and determines a point of time when the error accumulated average value is outside a reference range as the etch endpoint.

12. The apparatus of claim 8, wherein the captured image is an image restored in a predetermined space in the plasma chamber.

13. The apparatus of claim 8, wherein the captured image is an image restored in a space corresponding to a plasma sheath.

14. The apparatus of claim 8, further comprising:
a laser unit for generating a laser beam;
a beam splitter for splitting the generated laser beam into a beam in a horizontal direction facing the plasma chamber and a beam in a vertical direction facing upward;
a beam expander for expanding the beam in the horizontal direction towards a chuck upper portion where a wafer is placed in the plasma chamber; and
a charge coupled device (CCD) sensor for obtaining the captured sensor by receiving a beam reflected from an inner wall of the plasma chamber after passing through the chuck upper portion, through the beam splitter.
